(19) United States
(12) Patent Application Publication
(10) Pub. No.: US 2003/0103385 A1
(43) Pub. Date: Jun. 5, 2003

(54) Method pf processing a write command

(76) Inventor: Jose Mennecart, Dry (FR)

Correspondence Address: LEONARD W. POJUNAS, SCHLUMBERGERSEMA, INC., 30000 MILL CREEK AVENUE, SUITE 100, ALPHARETTA, GA, 30022, US

(21) Appl. No.: 10/276,215

(22) PCT Filed: May 17, 2001
(86) PCT No.: PCT/IB01/00862

(30) Foreign Application Priority Data
May 17, 2000 (FR) 00/06277

(51) Int. Cl. G11C 7/00

(52) U.S. Cl. 365/189.01

(57) ABSTRACT

A write command comprises a definition of a memory zone (ZN) followed by data to be stored in that memory zone. Such a write command may be, for example, a write command in accordance with ISO 7816 standard relating to smart cards. The write command is processed in the following manner. In a receiving step (F4), the data is written into a buffer memory (RAM). In an erasure step (F3), the memory zone (ZN) defined by the write command is erased while the data is written into the buffer memory (RAM). Thus, the receiving step (F4) and the erasure step (F3) are, at least partially, effected in parallel. In a transfer step (F7), the data is transferred from the buffer memory (RAM) to the memory zone (ZN) defined by the write command.

### FIELD OF THE INVENTION

The present invention relates to the processing of a write command that comprises a definition of a memory zone followed by data to be stored in that memory zone. Such a write command may be, for example, a write command in accordance with ISO 7816 standard relating to smart cards.

### BACKGROUND OF THE INVENTION

Smart cards generally comprise an electrically erasable programmable read-only memory (EEPROM). EEPROMs store data in non-volatile manner such that the data remains recorded in the memory even when the memory is unpowered. They also allow data to be updated by erasing all or part of the memory and by writing new data. The erase operation is performed electrically by applying a high voltage to the memory.

FIG. 1 is a block diagram of the electrical portion of a smart card. The circuit shown in FIG. 1 comprises a microcontroller 1 constituting the electronic chip of the card, and an interface 2 enabling the card to communicate with a read/write terminal (not shown).

The microcontroller 1 mainly comprises a microprocessor 10, memory units 20, 30, 40, an input/output circuit 50, and a data bus 60 connecting the circuits 20, 30, 40, and 50 to the microprocessor 10. The memory units 20 and 30 respectively comprise a read-only memory (ROM) containing a computer program known as the “operating system” which governs operation of the chip, and a random access memory (RAM) for temporary storage of data being processed by the microprocessor 10.

The EEPROM unit 40 serves to store data specific to the user, such as name, secret code (PIN), or a sum of money that is available. With reference to FIG. 2, the memory 40 includes in particular an EEPROM 400, a voltage-raising module 410 for erasing data stored in the memory 400, and a register 420 containing a flag whose binary “0” or “1” state indicates whether the process of erasing the memory 400 has terminated or not.

The interface 2 can be constituted by electrical contacts suitable for co-operating with corresponding electrical contacts of a read/write terminal, and/or by radio transceiver means suitable for interchanging radio signals with the terminal, where such transceiver means are said to provide “contactless” connection. A smart card equipped for contactless connection can be used, for example, as an electronic purse. The user can then perform a transaction such as purchasing an article, by passing the card into an electromagnetic field produced by the terminal and serving, amongst other things, to power the chip with electricity.

FIG. 3 shows a conventional method of updating data in the EEPROM 400 of FIG. 2. In a first step E1, the data is received by the microprocessor 10 via the interface 2 and the input/output circuit 50. Each data item received is temporarily stored in the RAM 30 (step E2). In the following step E3, a zone of the EEPROM 400 containing the data to be updated is erased by means of the voltage-raising module 410 under the control of the microprocessor 10. When the register 420 indicates that erasing is complete, then the received data is extracted from the RAM 30 for writing in the above zone (step E4).

A major drawback of that method lies in the fact that it is relatively lengthy to implement. This is particularly troublesome when using contactless smart cards since it is difficult under such circumstances to control the length of time the smart card spends in the electromagnetic field of the terminal. This time depends on how fast the user handles the card. All of the operations associated with communicating with the terminal, including the operations of erasing and writing in the EEPROM, must therefore be performed as quickly as possible. In practice, it is accepted that together these operations must not require more than a few tens of milliseconds. Unfortunately, a single transaction can require a plurality of erasing and writing operations in the memory, and each of those operations on its own can require several milliseconds.

### SUMMARY OF THE INVENTION

The present invention seeks to reduce the time required for processing a write command that comprises a definition of a memory zone followed by data to be stored in that memory zone.

To this end, the processing is carried out in the following manner. In a receiving step, the data is written into a buffer memory. In an erasure step, the memory zone defined by the write command is erased while the data is written into the buffer memory. In a transfer step, the data is transferred from the buffer memory to the memory zone defined by the write command.

Thus, the receiving step and the erasure step are, at least partially, effected in parallel. Consequently, the invention reduces the time required to process the write command concerned compared with the conventional method described hereinbefore.

The memory zone of interest may be located, for example, in an electrically erasable programmable read-only memory (EEPROM). The EEPROMs presently available on the market generally require several milliseconds to be erased. During this time, all or part of the relevant data can be received and temporarily stored in the buffer memory.

These and other characteristics and advantages of the present invention will appear on reading the following detailed description given with reference to the accompanying drawings.

### BRIEF DESCRIPTION OF THE DRAWINGS

FIG. 1, described above, is a block diagram showing the electrical portion of a smart card;

FIG. 2, described above, shows greater detail of an EEPROM unit contained in the FIG. 1 apparatus;

FIG. 3, described above, shows a conventional algorithm for updating data in an EEPROM; and

FIG. 4 shows an algorithm of the invention for updating data in an erasable memory.

### DETAILED DESCRIPTION OF THE INVENTION

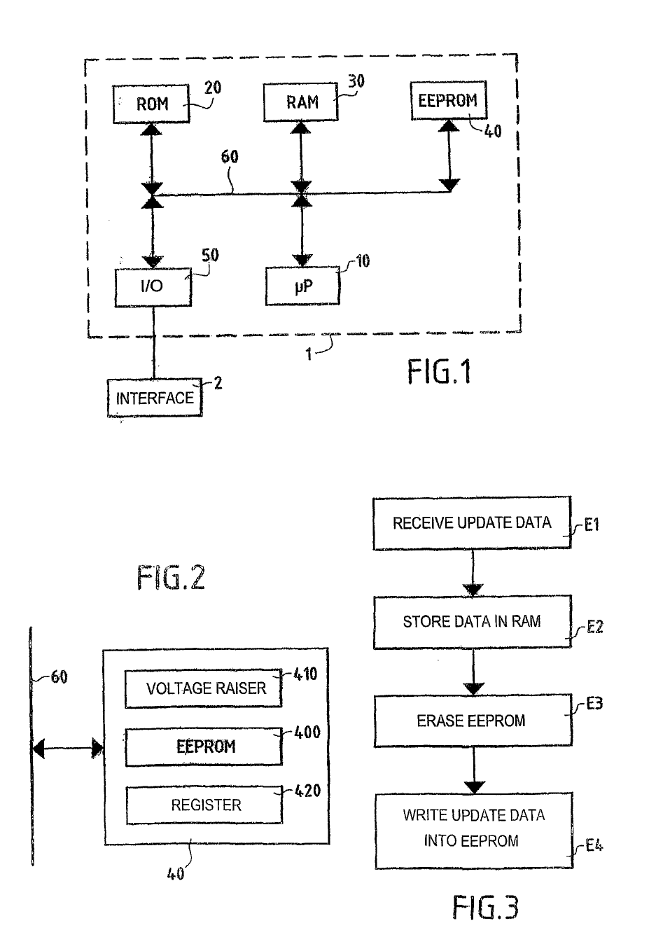

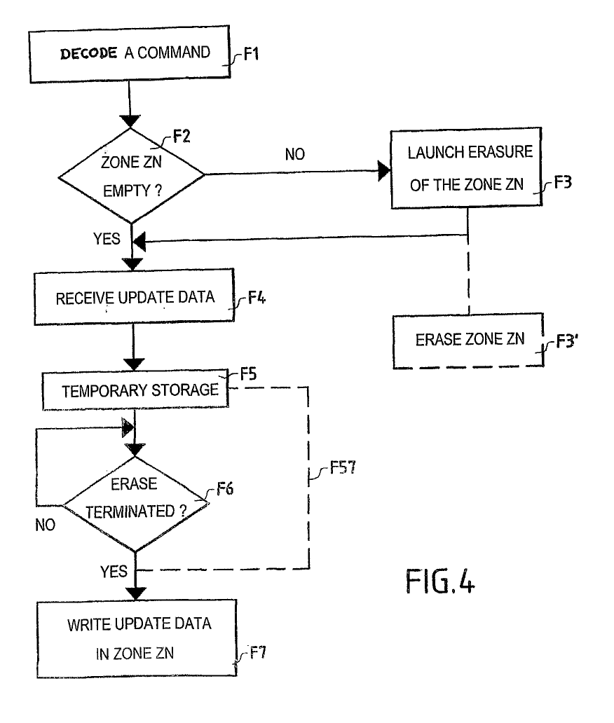

FIG. 4 illustrates an algorithm in accordance with the invention. The algorithm as shown in FIG. 4 is stored in the microcontroller 1 of the smart card illustrated in FIG. 1. More particularly, the algorithm is stored in the ROM 20 in the form of a computer program, for example, as a subprogram in the operating system of the microcontroller 1.

It is assumed that the smart card illustrated in FIG. 1 is coupled to a read/write terminal. It is further assumed that the read/write terminal applies a write command followed by data to the smart card in compliance with ISO standard 7816. An ISO 7816 command typically comprises five bytes, CLA, INS, P1, P2, P3. CLA is a byte that indicates the type of card for which the command is intended. INS is a byte that indicates the type of command. In the case of a write command, P1 and P2 are two bytes that indicate a start address and P3 is a byte that indicates the size of the data that needs to be written into the smart card in terms of number of bytes.

When the smart card receives the write command, it causes an interruption that activates the microcontroller 1 illustrated in FIG. 1. The microprocessor 10 receives the write command from the read/write terminal via the interface 2 (with or without contact) and via the input/output circuit 50 illustrated in FIG. 1.

In a first step F1, which is illustrated in FIG. 4, the microprocessor 10 decodes the write command. Accordingly, the microprocessor recognizes, as it were, that it is going to receive update data for writing in a zone ZN of the EEPROM 400 illustrated in FIG. 2. As described hereinbefore, EEPROM 400 forms part of EEPROM unit 40 illustrated in FIG. 1.

In the following step F2, the microprocessor 10 determines whether the zone ZN is empty. If the response to step F2 is “no”, then an operation of erasing the data contained in the zone ZN is started in a step F3, by activating the voltage-raising module 410 of the EEPROM unit 40. The zone ZN is then erased (step F3′) independently of the progress of the algorithm through the microprocessor 10, as represented by dashed lines in FIG. 4. Thus, while erasure is taking place, the microprocessor can receive the update data from the read/Write terminal in a step F4 and can store each data item in the RAM 30 (step F5).

If step F2 determines that the zone ZN contains no data, then the microprocessor 10 waits until it has received the update data prior to implementing steps F4 and F5.

Once the update data has been received and stored in the RAM 30, and if initially the zone ZN was not empty (step F2), then in a step F6, the microprocessor verifies whether erasure of the zone ZN has terminated. To do this, the microprocessor 10 interrogates the register 420 of the EEPROM unit 40. If the flag contained in this register indicates that erasure has not terminated, then the microprocessor 10 repeatedly interrogates the register 420 at regular time intervals until this flag changes state.

Once the flag indicates that erasure has terminated during a verification performed in step F6, then the zone ZN is updated by writing therein the data stored in the RAM 30 (step F7).

If it is found in step F2 that the zone ZN is empty, then step F6 is omitted, with the algorithm passing directly from the reception and storage steps F4, F5 to the write step F7, as represented by dashed line F57.

The description hereinbefore with reference to the drawings illustrates the following basic characteristics. A write command comprises a definition of a memory zone (ZN) followed by data to be stored in that memory zone. The write command is processed in the following manner. In a receiving step (F4), the data is written into a buffer memory (RAM). In an erasure step (F3), the memory zone (ZN) defined by the write command is erased while the data is written into the buffer memory (RAM). Thus, the receiving step (F4) and the erasure step (F3) are, at least partially, effected in parallel. In a transfer step (F7), the data is transferred from the buffer memory (RAM) to the memory zone (ZN) defined by the write command.

The present invention as described above and as defined in the accompanying claims is not limited to a zone ZN constituting part only of the EEPROM 400. The zone ZN could constitute the entire erasable memory.

Furthermore, the present invention can be applied to apparatuses other than smart cards, and in particular to other types of portable appliance.

1/ A method of processing a write command comprising a definition of a memory zone followed by data to be stored in that memory zone, the method comprising:
a receiving step in which the data is written into a buffer memory;
an erasure step in which the memory zone defined by the write command is erased while the data is written into the buffer memory; and
a transfer step in which the data is transferred from the buffer memory to the memory zone defined by the write command.

2/ An apparatus capable of processing a write command comprising a definition of a memory zone followed by data to be stored in that memory zone, the apparatus comprising a controller which in response to said write command causes the apparatus to effect the following steps:
a receiving step in which the data is written into a buffer memory;
an erasure step in which the memory zone defined by the write command is erased while the data is written into the buffer memory; and
a transfer step in which the data is transferred from the buffer memory to the memory zone defined by the write command.

3/ A smart card capable of processing a write command comprising a definition of a memory zone followed by data to be stored in that memory zone, the smart card comprising a controller which in response to said write command causes the smart card to effect the following steps:
a receiving step in which the data is written into a buffer memory;
an erasure step in which the memory zone defined by the write command is erased while the data is written into the buffer memory; and
a transfer step in which the data is transferred from the buffer memory to the memory zone defined by the write command.

4/ A computer program product for a smart card, the computer program product comprising a set of instructions which, when loaded into the smart card, causes the smart card to effect the following steps in response to a write command that comprises a definition of a memory zone followed by data to be stored in that memory zone
a receiving step in which the data is written into a buffer memory;
an erasure step in which the memory zone defined by the write command is erased while the data is written into the buffer memory; and
a transfer step in which the data is transferred from the buffer memory to the memory zone defined by the write command.
